(19) United States
(12) Patent Application Publication
(10) Pub. No.: US 2010/0117165 A1
(43) Pub. Date: May 13, 2010

(54) DEPOSITION OF LAYERS OF POROUS MATERIALS, LAYERS THUS OBTAINED AND DEVICES CONTAINING THEM

(75) Inventor: Antonino Secondo Fiorillo, Catona - Reggio Calabria (IT)

Correspondence Address: KNOBBE MARTENS OLSON & BEAR LLP, 2040 MAIN STREET, FOURTEENTH FLOOR, IRVINE, CA, 92614, US

(73) Assignee: UNIVERSITA DEGLI STUDI "MAGNA GRAECIA" DICATANZATO, Catanzaro/CT (IT)

(21) Appl. No.: 12/594,810

(22) PCT Filed: Mar. 28, 2008
(86) PCT No.: PCT/IT2008/000210

§ 371 Date: Oct. 5, 2009

(30) Foreign Application Priority Data
Apr. 4, 2007 (IT) RM2007A000189

(51) Int. Cl. H01L 29/66; C09D 191/00; B32B 3/10; B32B 3/26; B32B 1/00; H01L 21/30

(52) U.S. Cl. 257/414; 106/244; 428/141; 428/304.4; 428/174; 438/49; 257/E29.166; 257/E21.211

(57) ABSTRACT

The present invention describes a process for the deposition of one or more layers of zeolites on rigid supports of various natures and geometry, particularly on silicon wafers. The coating containing zeolites is characterised by pore sizes ranging from 1 Angstrom to a few nanometer units. The deposition process does not interfere with and/or alter the correct functioning of the electronic devices (diodes, bipolar junction transistors, field effect transistors and electronic amplifiers in general) already integrated on the support to be coated on which said deposition is effected. The process according to the invention can be applied to electronic devices and permits their unaltered correct functioning.

### FIELD OF THE INVENTION

The present invention relates to the deposition of layers of porous materials on supports, to the layers (or coatings or covers) thus obtained and to the devices containing them, particularly electronic devices that can be used for the detection and measurement of chemical and physical parameters of biological, medical and industrial interest.

### STATE OF PRIOR ART

Processes of deposition of layers of porous materials are known, possibly in combination with other components such as metal oxides, in addition to metals and non-metals, in mixtures with volatile substances for the production of gas sensors sometimes defined as solid-state semiconductor gas sensors. The above-mentioned sensors are not produced with the technology of integrated circuits (IC) and said layers are deposited directly on isolating supports or semiconductor supports such as silicon wafers, The technologies developed to produce said layers include processes of vacuum evaporation, sputtering, chemical vapour-phase deposition, spray deposition, and solution deposition. In addition to their often high cost, all these techniques present numerous problems that render them incompatible with the microfabrication processes of electronic circuits and integrated circuits on silicon wafers, save at the expense of substantial alterations of the treated supports and the electronic circuits therein included. In addition, from the structural point of view, the porous materials grown or deposited with the existing techniques present numerous defects such as partial or total occlusion of the pores, non-reproducibility, non-uniformity of the layers and poor process flexibility (in terms of insertion in the current production cycles of electronic devices including them).

For example, spray deposition implies a substantial modification of the manufacturing cycle of integrated electronic circuits due to the introduction of a deposition system that is infrequent in these manufacturing processes and to the problems related to polluting volatile solvents, the disposal of which, in this type of deposition, requires particular control operations. Another problem of this technique consists in the need to heat the substrate to high temperatures during deposition and this may, in some cases, increase the harmfulness of the solvents used, and, in other cases, damage the electronic circuits already integrated on the semiconductor support. Other problems related to the non-uniformity of the layers caused by turbulence of the spray or the flow rate are described in U.S. Pat. Nos. 4,453,151 and 4,601,914.

Direct deposition of solutions is used more frequently, but requires excessive operator intervention and fails to guarantee the necessary reproducibility, whereas growth of the deposition product directly on the silicon substrate, used in some cases as the base of the autoclave employed for the crystallisation process, is time-consuming, expensive and inapplicable in an industrial manufacturing process of integrated electronic circuits, but is useful only for research purposes in the laboratory. Thus, in-situ crystallisation and other processes of a hydrothermal nature used for the production of devices on silicon wafers present limitations in terms of their poor compatibility with the manufacturing processes of integrated electronic circuits and therefore also of integrated sensors.

The sputtering technique, though compatible with integrated circuit technology, is expensive and introduces additional steps in the processing of electronic microcircuits which require operator intervention on high-vacuum machines with a resulting increase in production costs, without considering that this technique may damage the integrated circuits to which it is applied.

The spin-coating technique (Wang et al.: Pure silica zeolite films as low-k dielectrics by spin-on of nanoparticle suspensions, Adv. Mater. 2001, 13, No 19, October 2, Wiley-VCH Verlag Ed.), involves the dissolution or dispersion of the material to be deposited in a solvent and the deposition of the mixture thus obtained on the surface concerned, with subsequent removal of the solvent by means of suitable heat treatment, to leave a uniform layer of the material deposited. It is compatible with integrated circuit technology, is known to the expert in the field and is normally used in the photolithographic technique for the deposition of the photoresist for the purposes of defining areas of intervention on the silicon wafer or wafer of other semiconductor material, by means of subsequent illumination with UV light through suitable masks. This technique has been proposed for the deposition of zeolites on silicon supports, but not on ICs, starting from tetrapropylammonium hydroxide/tetraethoxysilane/ethyl-alcohol/water (TPAOH/TEOS/EtOH/H₂O) solutions, subsequently submitted to centrifuging to remove zeolite agglomerates measuring more than a micrometer in size. This zeolite suspension is then deposited by spinning on the support to be treated and fixed to it by means of a calcination process at a temperature of 450° C., thus obtaining a film with a thickness ranging from 3 to 16 μm. On account of its complexity and the high temperatures required for calcination, this process is not compatible with the production techniques of integrated electronic circuits, which do not support maximum working temperatures over 70-80° C. for uses in the commercial field or even above 125° C. for uses in the military field (Horowitz P. and Hill W. The art of electronics, Cambridge University Press, Cambridge 1987).

None of the existing techniques, then, makes it possible to obtain uniform layers of zeolites at low cost, with a procedure that is simple, rapid, reproducible in terms of end products and compatible with current production technologies of integrated microelectronic circuits on silicon wafers, or other semiconductor materials, such as, for example, gallium arsenide or germanium, or on non-conductor supports and supports with planar geometry or variously complex geometries or geometries other than planar, e.g. cylindrical, for the production of sensors or integrated electronic devices.

### SUMMARY OF THE INVENTION

The purpose of the present invention is therefore to produce a process with none of the above-mentioned drawbacks, which allows the deposition of one or more layers of zeolites on rigid supports of various natures and geometry, particularly on silicon wafers.

The coating containing zeolites according to the invention is typically characterised by pore sizes ranging from 1 Angstrom to a few nanometer units, typically from 1 Angstrom to 5 nanometers, preferably from 2 Angstroms to 4 nanometers, and more preferably from 3 Angstroms to 2 nanometers.

It is also the purpose of the invention to produce a process that allows deposition without the aid of solvents, implementable at temperatures ≦200° C., preferably temperatures that do not damage the electronic circuits, in which the material deposited is in the form of one or more rough layers with an average roughness ranging from 1 μm to 3 μm and the zeolite deposited is in direct contact with the support, without the interposition of layers of adhesives or adhesion primers.

A further purpose of the present invention is to produce a deposition process as above, capable of not interfering with and/or altering the correct functioning of the electronic devices (diodes, bipolar junction transistors, field effect transistors and electronic amplifiers in general) already integrated on the substrate to be coated, in particular silicon, on which said deposition is effected. The process according to the invention can be applied to supports designed for guided light, such as, for example, optical fibres and the sensors produced with them, and allows their unaltered correct functioning.

The deposition can be accomplished by spin-coating or other techniques such as dipping, or brush, jet or roller application when a high degree of uniformity of the coating layer is not required.

The application of the zeolite layer can be done in a broad temperature range from 35° C. to 125° C., more preferably from 55° C. to 100° C., and even more preferably from 70° C. to 90° C., bearing in mind that at lower treatment (or cooking) temperatures there will be correspondingly longer heat treatment times. Furthermore, in the case of substrates not containing microelectronic circuits or particular sensors and microelectromechanical systems, for example of the MEMS (Micro-Electro-Mechanical Systems) or QCM (Quartz Crystal Microbalance) type, connected to them, the heat treatment can reach temperatures of 200° C. or more (Yan, Y. and Bein T.: Zeolite thin films with tunable molecular sieve function, J. Am. Chem. Soc. 1995, 117, 9990-9994).

The porous materials used for the deposition according to the invention belong to the zeolite class (Virta R. L.: Zeolites, U.S. Geological Survey Minerals Yearbook, 1999, 84.1-84.3). The materials preferred are the natural or synthetic zeolites, known in the field of chemistry as zeolites A3, A4, A5, X10, Y10, and Alpo, which can also be used in mixtures thereof with a granulometry ranging from 500 nm to 5 micrometers.

The zeolites to be deposited are used in mixtures with an organic vehicle of the vegetable oil type, such as, for example, unsaturated fatty acids containing straight- or branched-chain hydroxyl groups with from 15 to 25 carbon atoms; the preferred vehicles are oleic, linoleic and ricinoleic acid; particularly preferred is castor oil. The organic vehicle, in process conditions, will not be subjected to evaporation, but to a sort of “caramelisation”, or rather reticulation, in such a way as to incorporate the zeolite and retain it on the substrate to be coated. Preferably, the weight-by-weight ratio of zeolite to organic vehicle to be reticulated should range in the interval 30-70%, preferably 40-60%, and more preferably 50-50%.

The “cooked” organic vehicle guarantees the cohesion of the microagglomerates, in addition to the adhesion of the latter to the silicon substrate or substrate of other semiconductor, conductor or isolating material, without reducing or modifying the absorption and exchange capacity of the zeolite itself. With the process according to the invention it proves possible to obtain a coating in which the incorporated zeolite maintains its initial properties, and thus the process according to the invention makes it possible to produce an “active” or activatable layer, in that it contains zeolites that maintain their characteristic physico-chemical properties unaltered, for example, capturing the substance to be detected (enzyme or other type of substance) by placing it in direct communication with the underlying electronic part. Essentially, the zeolite maintains its own functionality, i.e. it behaves exactly as if it were not incorporated in the “caramelised” oil.

One last purpose of the present invention is to produce a deposition process for the manufacture of one or more zeolite layers, each with a different degree of porosity, for example, using zeolites of different type or nature, e.g. zeolites of different porosity, at each successive deposition step.

The sensors and electronic devices that the technique proposed makes it possible to manufacture are generally of the solid-state type and can be integrated on wafers, preferably of silicon or some other semiconductor material, thus obtaining direct contact between the zeolite and the integrated electronic circuits on the support. The direct contact makes it possible to obtain electrical continuity or field effect between zeolite and electronic circuit.

The coating according to the invention can be used advantageously inside electronic devices that incorporate it and to produce sensors for the detection and measurement of chemical species compatible with the porosity of the coating.

Further purposes will be evident from the following detailed description of the invention.

### BRIEF DESCRIPTION OF THE FIGURES

FIG. 1 is a schematic representation of the cross-section of a solid-state electronic device integrated on a silicon wafer.

FIG. 2 shows the image of the surface of the layer of the castor oil/zeolite mixture deposited on the MOS gate, obtained with a “Combined System SEM-Microanalysis” scanning electron microscope marketed by Fei—XT Nova Nanolab—Edax.

FIG. 3 presents another image obtained with the same instrumentation, showing a section of the layer of zeolite mixture deposited on an unprocessed silicon wafer.

### DETAILED DESCRIPTION OF THE INVENTION

The deposition method according to the invention makes it possible to produce an authentic zeolite-based cover or coating, directly deposited on the support without the use of interposed adhesive layers or adhesion primers, so as to constitute the intermediary between the substance or substances to be detected and the underlying detection device. In practice, the coating according to the invention exploits the intrinsic characteristics of the zeolites and permits the absorption and release of substances also of a biological nature, e.g. enzymes and proteins, (Lee, G. S. et al.: Self-assembly of β-glucosidase and D-glucose-tethering zeolite crystals into fibrous aggregates, J. Am. Chem. Soc. 2000, 122, 12151-12157. Um, S. H. et al.: Self-assembly of avidin and D-biotin-tethering zeolite microcrystals into fibrous aggregates, Langmuir 2002, 18, 4455-4459. Poletto, M. et al.: Hydrolysis of lactose in a fluidized bed of zeolite pellets supporting adsorbed β-galactosidase, I. J. Chem. Reac. Eng. 2005, 3, A43. Liu, B. et al.: An amperometric biosensor based on the coimmobilization of horseradish peroxidase and methylene blue on a β-type zeolite modified electrode, Fresenius' J. Anal. Chem., Springer, 2000, 367(6), 539-544), in addition to ions and/or molecules (Virta R. L.: Zeolites, U.S. Geological Survey Minerals Yearbook, 1999, 84.1-84.3) whose minimum dimensions are compatible with those of the pores of the zeolites deposited with the technique claimed.

The deposition technique may be that of spin-coating or even simply of dipping the substrate in the oily vehicle/porous material mixture.

In the eventuality that the mixture is applied by spin-coating, the spin-coating device will advantageously comprise a chamber containing the sample-holder, or spinner, which is rotated in order to ensure the uniformity of the coating deposited on the surface of the support to be coated.

In spin-coating the process comprises the following stages:

(i) after preparing the zeolite mixture in a suitable oily vehicle, cleanse thoroughly the surface of the support to be coated;
(ii) place the surface on the spinner in a perfectly horizontal position and deposit the mixture, for example with a mechanical or electromechanical metering device and/or by spreading it, covering the underlying surface completely. The amount deposited will be such as to permit a layer to be obtained with an average thickness of approximately 5-50 μm, preferably 10-30 μm, with an average roughness ranging from 1 μm to 3 μm; then spin the surface at a speed of 2000-6000 rpm, preferably 3000-4500 rpm, for a time period ranging from 30 to 90 seconds, preferably 50 to 60 seconds;
(iii) place the support, e.g. silicon wafer, in an oven in a perfectly horizontal position and heat at a temperature ranging from 35° C. to 125° C., more preferably from 55° C. to 100° C., and even more preferably from 70° C. to 90° C. for a time period ranging from 5 to 15 hours, preferably 7 to 10 hours, so as to cook the oil of the mixture, ensuring that the zeolite remains stably positioned on the surface of the support and at the same time immersed in the organic matrix consisting of the “cooked” or “caramelised” oily vehicle;
(iv) leave the layer/support assembly to cool to the desired temperature, generally room temperature.

Stages (ii), (iii) and (iv) can be repeated several times, even with mixtures of different types both in terms of zeolites and in terms of the dispersing vehicle and with different operating conditions in such a way as to obtain a series of superimposed layers, also with different characteristics, the final thickness of which may even be several tens of micrometers.

The same technique can also be applied with the same modalities on unprocessed silicon supports or on supports of some other semiconductor material or on isolating supports, such as those made of plastic, polymeric supports in general, such as, for example, piezoelectric polyvinylidenefluoride (PVDF)-based polymers or vinylidenefluoride/trifluoride/trifluoroethylene P(VDF-TrFE) co-polymers and semiconductor polymers such as, for example, the polypyrroles (Ppy), or also those deposited on silicon wafers with the same technique described in U.S. Pat. No. 5,254,504.

The microporous and mesoporous layers according to the invention can be used to produce electronic devices or electromechanical systems (MEMS), which are known to the expert in the field, and which are suitable for detecting and measuring physical and chemical magnitudes generated by the interaction of the zeolites with the external environment, thanks to their characteristics, which act as an absorbing matrix for biological, chemical and pharmacological substances, in that the zeolite deposited constitutes a matrix whose electrical characteristics are made to vary by the biospecies absorbed.

The technique claimed in the present invention makes it possible to produce a single integrated system in which an isolating support (e.g. a polymeric substrate) or semiconductor or conductor of electricity is placed in intimate contact with the mono- or multilayer coating according to the invention. In particular, the support can have planar geometry and bear conductor tracks obtained with a technique with which experts in the field of microtechnology are familiar, such as, for example, in the case of surface acoustic wave (SAW) sensors, or may contain piezoelectric materials such as those used to produce quartz crystal microbalances (QCM). In particular, also, the support is a planar semiconductor support, preferably made of silicon and, as already defined above, can advantageously be a “processed silicon wafer” because elementary microelectronic circuits have already been produced on it, such as diodes, bipolar junction transistors (BJT), field effect transistors (MOSFET) or more complex microelectronic circuits, such as differential amplifiers, operational amplifiers, filters and other devices suitable for generating electrical signals or for acquiring and elaborating the latter when these have been produced by the interaction between one or more zeolite-based layers, deposited with the technique claimed herein, and the external environment. The field effect transistors can be of the extended gate type similar to those already described in U.S. Pat. No. 5,254,504 for the production of ferroelectric sensors based on MOSFET technology (Metal Oxide Semiconductor Field Effect Transistor). One or more conductor terminals of said electronic circuits can be in intimate contact with the layer of porous material deposited, in such a way as to produce a single integrated system. Said contact may be extended to the entire surface of the layer of zeolite-based porous material or to part of it.

In general, the supports taken into consideration, irrespective of their geometry, which can also be non-planar, e.g. cylindrical, may be capable of guiding electromagnetic waves, such as, for example, in the case of optical fibres.

### DESCRIPTION OF A PREFERRED EMBODIMENT OF THE INVENTION

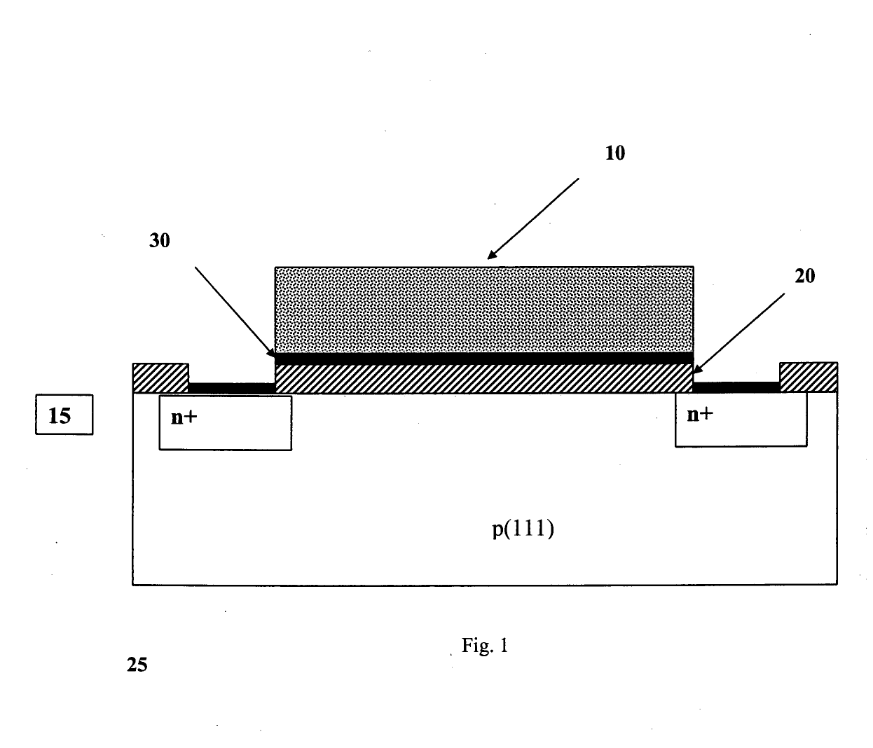

There now follows a description, also with the aid of FIG. 1, of a first preferred embodiment, according to the invention, of a system with a stratified structure and planar geometry comprising a support, (25), also called substrate, which can be made of glass or some other isolating or semiconductor material or conductor of electricity, particularly intrinsic or doped silicon of the type used in the manufacture of integrated electronic circuits. On this support, or substrate, is deposited a layer of conductor material, (30), of the type used in the manufacture of integrated electronic circuits, such as for example, gold or aluminium, or a thin layer of polysilicon or silicon dioxide, (20), is grown with technologies which are in themselves known, with one of the techniques used in the microelectronics sector, for example, as described in Sze, S. M.: Semiconductor sensors, Wiley Interscience, NY, 1994; and Wolf, S. and Tauber, R. N. Silicon Processing, Lattice Press, Sunset Beach, Calif., 1986. These layers can also be simultaneously present and superimposed or alternated with one another, such as, for example, in a planar metal/silicon dioxide/metal condenser structure. The thicknesses of these layers, single or alternated, are those typical of the technology of integrated electronic circuits on silicon wafers. On this layer, if there is only a single layer, or on the outermost layer, if there is more than one layer, is deposited, in an integral manner (i.e. without interposing other layers of adhesive material) a film consisting of a mixture of A₃-type zeolites, in a proportion of 50% of the total weight, and castor oil. The porous material generally has pores of sizes ranging from approximately 3 nanometers to 3 Angstroms. The zeolite film deposited on the substrate with the technique described in the present invention has a thickness which, in its final composition, ranges from 5 μm to 40 μm, with an average roughness ranging from 1 μm, for thin films, to 3 μm, for thicker films.

In another embodiment of the present invention (not shown) the zeolite film, of the same composition as described above, can also be deposited on a cylindrical support made of glass or some other isolating or semiconductor material or conductor of electricity, for example, on optical fibres simply by dipping the support in the zeolite/oil mixture one or more times until the desired thickness is obtained, which, in its final composition, ranges from a few μm to several tens of μm, preferably from 5 μm to 40 μm, with an average roughness ranging from 1 μm, for thin films, to 3 μm, for thicker films.

FIG. 1 shows the cross-section of a possible solid-state electronic device integrated on a type p(111) silicon wafer with 6-20 Ωcm resistivity, (25), composed of a field effect transistor of the N-channel MOS type, in which two zones doped with n+ donor atoms, (15), which equivalently create the Drain or the Source of the device, are subsequently metallised for the formation of the respective electrodes, (30). A third electrode, Gate, is formed between the Drain and the Source above a layer of silicon dioxide, (20); this can also be of the extended type as described in U.S. Pat. No. 5,254,504 and is surmounted by the zeolite/castor oil mixture layer, (10).

In the case of BJT bipolar transistors the zeolite/castor oil mixture layer may be in contact with the Base electrode to modulate the current as a function of the species absorbed or of the ions trapped, or of enzymes in intimate contact, etc.

The silicon wafer may include (though not necessarily) one or preferably multiple electronic devices integrated in it (not shown), which may have one or more terminals in contact with the zeolite film described. In particular, the zeolite-based mixture can be deposited in such a way as to cover one or more terminals of the integrated electronic devices on the silicon wafer, diodes, bipolar junction transistors, field effect transistors. For example, the film of material may be deposited on the gate terminal of one or more MOSFET field effect transistors, to receive from the external environment electrical, chemical, and biological information, or information regarding some other form of energy, for example mechanical (as in the case of MEMS). Other circuits can be integrated in the silicon wafer to increase the signal to noise ratio, to amplify, filter and, in general, condition the electrical signal originated in the external environment by one of the above-mentioned forms of energy. On the other hand, yet other integrated circuits can be used, to generate electrical signals that interact with the zeolite itself in order to stimulate or facilitate, for example, the exchange of ions and atoms with the external environment.

The zeolite used is in the form of crystalline microagglomerates the maximum size of which ranges preferably from a few tens of nanometers to a few micrometers, as illustrated in the SEM microphotographs in FIGS. 2 and 3. The mixture contains zeolite dispersed in castor oil, in the above-mentioned percentages, and is deposited with the spin-coating technique in the following manner: the processed silicon wafer is washed with isopropyl alcohol, then with deionised water and finally dried with a nitrogen jet; the wafer is carefully placed on the spinner in a perfectly horizontal position and the mixture is deposited on the processed silicon wafer which is then spun at a speed of 3500 rpm for 60 seconds so as to form a uniform layer with an average thickness of approximately 10 μm; the silicon wafer is placed in an oven in a perfectly horizontal position at a temperature of approximately 100° C. for 7 hours, so as to heat treat the oils of the mixture and promote both cohesion between the zeolite microagglomerates and adhesion of the film to the wafer, thus obtaining an integral device in which the porous material remains immersed in a matrix with a high percentage of carbon; the silicon wafer is left to cool spontaneously to room temperature and prepared for a new deposition of the same zeolite or of a zeolite with a different degree of porosity.

In the eventuality that stage (ii) is repeated twice an integral device is obtained with a double layer of zeolite with a thickness of approximately 25 μm in which each layer has the same or even a different degree of porosity.

The same technique can be repeated with the same modalities also on unprocessed silicon supports or supports made of some other semiconductor material or on isolating supports or on electricity conductors. The data in Table 1 illustrate the dependence of the thicknesses of the zeolite films on the duration of a single deposition after cooking in the oven at 120° C. for 10 hours. The data refer to a 50% paste of zeolites A₃ and A₅ (the reader is referred to FIGS. 2 and 3) and castor oil.

TABLE 1

| Speed (rpm) | 3500 | 3500 | 3500 | 3500 |
|---|---|---|---|---|
| Duration of deposition (s) | 30 | 40 | 50 | 60 |
| Average thickness (μm) | 37 | 29 | 20 | 11 |

1. Composition comprising zeolites with a granulometry ranging from 500 nm to 5 micrometers and a vegetable oil selected from the group consisting of unsaturated fatty acids containing straight- or branched-chain hydroxyl groups with from 15 to 25 carbon atoms wherein a weight-by-weight ratio of zeolite to vegetable oil ranges from 30% to 70%.

2. Composition according to claim 1, in which the zeolites are selected from the group consisting of natural or synthetic zeolites.

3. Composition according to claim 1, in which the zeolites have pore sizes ranging from 3 Angstroms to 2 nanometers.

4. Coating layer for electronic supports containing the composition according to claim 1.

5. Coating layer according to claim 4 with a thickness ranging from 5 μm to 50 μm and with an average roughness ranging from 1 μm to 3 μm.

6. Coating layer according to claim 4 with an average porosity ranging from 3 Angstroms to 2 nanometers.

7. Coating layer according to claim 4, in which the electronic support is a planar or curved or cylindrical or irregular surface.

8. Coating layer according to claim 7, in which the electronic support is selected from the group of silicon substrates, semiconductor substrates, conductor substrates, and isolating material.

9. Coating layer according to claim 8, in which the substrate is made of polymeric material selected from the group consisting of the piezoelectric polymers of polyvinylidenefluoride (PVDF), vinylidenefluoride/trifluoro-ethylene P(VDF-TrFE) copolymers, semiconductor polymers, and polypyrroles (Ppy).

10. Coating layer according to claim 8, in which the substrate is a processed silicon wafer bearing at least one microelectronic circuit selected from the group consisting of diodes, bipolar junction transistors, field effect transistors, differential amplifiers, operational amplifiers, filters, and combinations thereof.

11. Electronic device containing one or more coating layers according to claim 4.

12. Device containing processed silicon wafers bearing at least one microelectronic circuit selected from the group consisting of diodes, bipolar junction transistors, field effect transistors, differential amplifiers, operational amplifiers, filters, and combinations thereof, said circuits being suitable for generating electrical signals or for acquiring and elaborating the latter when these have been produced by the interaction between one or more zeolite-based layers according to claim 4 and the external environment.

13. Electronic device according to claim 11, in which the zeolite deposited is in direct contact with the support, without any interposed adhesive layers or adhesion primers.

14. Electronic device according to claim 11, which is a solid-state-type sensor integrated on a wafer, the sensor being made of silicon or semiconductor material, and in which the zeolite deposited is in direct contact with the support, without the interposition of adhesive layers or adhesion primers, the direct contact making it possible to obtain electrical continuity or field effect between zeolite and electronic circuit.

15. Electronic device according to claim 11, wherein the device is configured to function as one selected from the group consisting of diodes, bipolar junction transistors, field effect transistors, electronic amplifiers, supports designed for guided light, MEMS, surface acoustic wave (SAW) sensors, piezoelectric devices, and quartz crystal microbalances (QCM).

16. Electronic devices bearing at least one of the layers according to claim 4 suitable for detecting and measuring physical and chemical magnitudes generated by the interaction between the zeolites and the external environment.

17. Devices according to claim 11, in which the zeolites act as an absorbing matrix for biological, chemical and pharmacological substances.

18. Deposition process of the composition according to claim 1 comprising applying the composition to the support to be accomplished by means of a technique selected from spin-coating, dipping, and brush, jet or roller application.

19. Process according to claim 18, in which the application of the composition is done at a temperature up to 250° C.

20. Process according to claim 18, in which application by spin-coating is implemented with a device equipped with a chamber containing a sample-holder, which is spun to ensure uniformity of the coating deposited on the surface of the support to be coated.

21. Process according to claim 20, in which the application by spin-coating comprising the following steps:
(i) after preparing the zeolite mixture in a suitable oily vehicle, cleansing thoroughly the surface of the support to be coated;
(ii) placing the support on the spinner in a horizontal position and depositing the mixture on the support, and then spinning the surface;
(iii) placing the support, in an oven in a horizontal position and heat at a temperature ranging from 60° C. to 250° C., for a time period ranging from 5 to 15 hours, so as to cook the oil of the mixture, ensuring that the zeolite remains stably positioned on the surface of the support and at the same time immersed in the organic matrix;
(iv) leaving the layer/support assembly to cool to the desired temperature;
optionally repeating stages (ii), (iii) and (iv) also with different compositions both in terms of zeolites and in terms of the dispersing vehicle and in different operating conditions to obtain a multiplicity of superimposed layers, also with different characteristics with final thicknesses of several tens of micrometers.

22. Composition according to claim 1, wherein the vegetable oil is selected from the group consisting of oleic acid, linoleic acid, ricinoleic acid, and castor oil.

23. Composition according to claim 1, wherein a weight-by-weight ratio of zeolite to vegetable oil ranges from 40% to 60%.

24. Composition according to claim 1, wherein the zeolites are selected from the group consisting of zeolites A3, A4, A5, X10, Y10, and Alpo, also in mixtures thereof.

25. Composition according to claim 1, wherein the zeolites have pore sizes ranging from 1 Angstrom to 2 nanometers.

26. Composition according to claim 1, wherein the zeolites have pore sizes ranging from 1 Angstrom to 5 nanometers.

27. Composition according to claim 1, wherein the zeolites have pore sizes ranging from 2 Angstroms to 4 nanometers.

28. Process according to claim 18, in which the application of the composition is done at a temperature up to 200° C.

29. Process according to claim 18, in which the application of the composition is done at a temperature ranging from 35° C. to 125° C.

30. Process according to claim 18, in which the application of the composition is done at a temperature ranging from 55° C. to 100° C.

31. Process according to claim 18, in which the application of the composition is done at a temperature ranging from 70° C. to 90° C.
